(19) United States
(12) Patent Application Publication
(10) Pub. No.: US 2013/0305988 A1
(43) Pub. Date: Nov. 21, 2013

(54) Inline Capacitive Ignition of Inductively Coupled Plasma Ion Source

(71) Applicants: William F. DiVergilio, Cambridge, MA (US); William D. Lee, Newburyport, MA (US); Mike Cristoforo, Beverly, MA (US); Walter Hrynyk, Needham, MA (US); Robert L. Moffett, Beverly, MA (US); Tomoya Nakatsugawa, Georgetown, MA (US)

(72) Inventors: William F. DiVergilio, Cambridge, MA (US); William D. Lee, Newburyport, MA (US); Mike Cristoforo, Beverly, MA (US); Walter Hrynyk, Needham, MA (US); Robert L. Moffett, Beverly, MA (US); Tomoya Nakatsugawa, Georgetown, MA (US)

(73) Assignee: Axcelis Technologies, Inc., Beverly, MA (US)

(21) Appl. No.: 13/475,006

(22) Filed: May 18, 2012

(51) Int. Cl. C23C 16/50; H05H 1/46

(52) U.S. Cl. 118/723 MP; 315/34

(57) ABSTRACT

An ion source is disclosed that utilizes a capacitive discharge to produce ignition ions, which are subsequently used to ignite an inductively coupled plasma within a plasma chamber. In some embodiments, a capacitive discharge element is located along a gas feed line at a position that is upstream of a plasma chamber. The capacitive discharge element ignites a capacitive discharge within the gas feed line. The capacitive discharge contains ignition ions that are provided to a downstream plasma chamber. An inductively coupled plasma ignition element, in communication with the plasma chamber, ignites and sustains a high density inductively coupled plasma within the plasma chamber based upon ignition ions from the capacitive discharge. Due to the ignition ions, the inductively coupled plasma element can easily ignite the high density inductively coupled plasma, even at a low pressure.

### BACKGROUND

Ion implantation is a physical process that is employed in semiconductor fabrication to selectively implant dopants into a semiconductor workpiece. Ion implantation can be performed in various ways in order to obtain a particular characteristic on or within a substrate (e.g., such as limiting the diffusivity of a dielectric layer on the substrate by implanting a specific type of ion).

During ion implantation, one or more ion species are generated by an ion source. Many commonly used ion sources are configured to provide energy to particles within a dopant gas (e.g., boron, phosphorus, arsenic, etc.) located within a plasma chamber. The energy excites particles within the dopant gas, which collide with neutral gas particles forming ions within an ionization chamber. When sufficient power has been delivered to the dopant gas, a plasma comprising a plurality of ions and electrons is ignited within the plasma chamber. Once the plasma is formed, ions are extracted from the plasma to form an ion beam that is delivered to a downstream workpiece.

### BRIEF DESCRIPTION OF THE DRAWINGS

FIG. 1 is a block diagram illustrating some embodiments to a disclosed plasma RF ion source comprising an inline capacitive discharge that produces ignition ions used to form an inductively coupled plasma.

FIG. 2 is a block diagram illustrating some additional embodiments of a disclosed plasma RF ion source.

FIG. 3 is a block diagram illustrating an exemplary ion implanter comprising a disclosed plasma RF ion source.

FIG. 4A illustrates some more particular embodiments of a disclosed ion source.

FIG. 4B illustrates a graph showing an exemplary pressure profile along the source flow path of ion source.

FIG. 5A illustrates some alternative embodiments of a disclosed ion source.

FIG. 5B illustrates a three dimensional illustration of ion source 500.

FIG. 6 illustrates a more detailed embodiment of a method for igniting an inductively coupled plasma.

### DETAILED DESCRIPTION

The present invention will now be described with reference to the drawings wherein like reference numerals are used to refer to like elements throughout.

Inductively coupled plasma RF ion sources are commonly used in ion beam implantation systems. Such ion sources are advantageous over other ion sources since they comprise simple designs that can deliver very high ion currents (e.g., compared to hot cathode DC discharge sources). However, inductively coupled plasmas are difficult to ignite, especially at low pressures wherein the ability of an RF power source to drive a plasma is reduced.

The inventors have appreciated that when the plasma in an ionization chamber is formed using an inductively coupled radio frequency (RF) source, initial ignition of the plasma can be accomplished with capacitive discharge in the source gas feed line. By initially igniting the plasma using capacitive discharge from an upstream gas feed line, the ability of the inductively coupled RF source to ignite and sustain a plasma is improved.

Accordingly, an ion source is disclosed that utilizes a capacitive discharge to produce ignition ions, which are subsequently used to ignite an inductively coupled plasma within a plasma chamber. In some embodiments, a capacitive discharge element is located along a gas feed line at a position that is upstream of a plasma chamber. The capacitive discharge element is configured to ignite and sustain a capacitive discharge within the gas feed line. The capacitive discharge comprises ignition ions that are provided to a downstream plasma chamber. An inductively coupled plasma ignition element, in communication with the plasma chamber, is configured to ignite a high density inductively coupled plasma within the plasma chamber based upon ignition ions from the capacitive discharge. Due to the ignition ions, the inductively coupled plasma element can easily ignite the high density inductively coupled plasma, even at a low pressure.

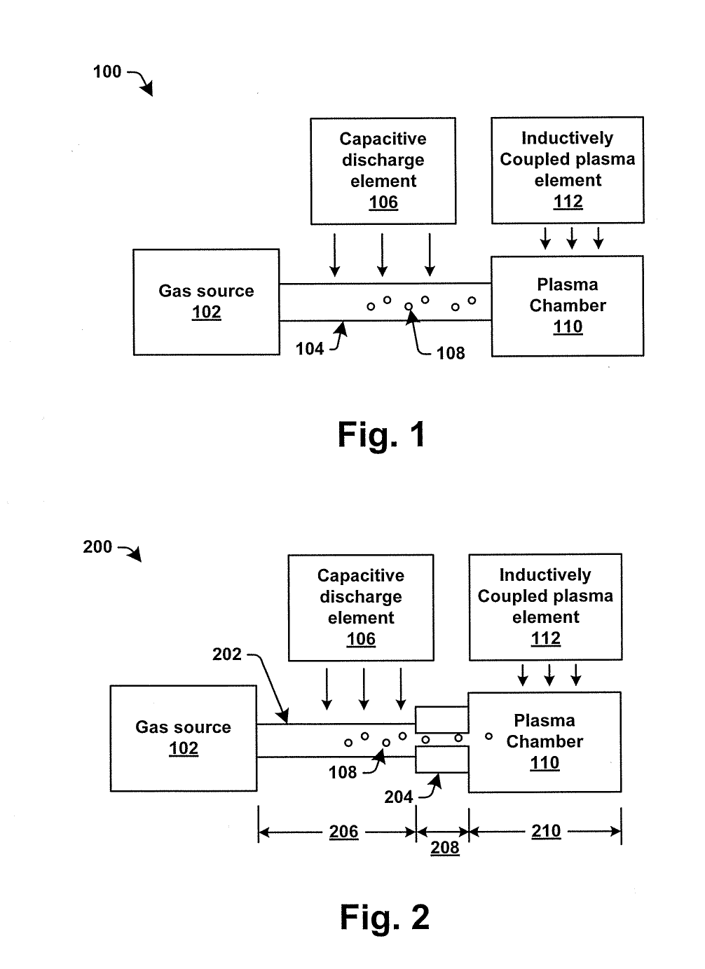

FIG. 1 is a block diagram illustrating some embodiments to a disclosed plasma RF ion source 100, as provided herein.

The disclosed plasma RF ion source 100 comprises a source flow path 104 along which dopant gas particles are conveyed from a gas source 102 to a plasma chamber 110. In various embodiments, the source flow path 104 may comprise a plurality of components, such as gas feed lines, gas feed tubes, gas flow restrictions, etc., which are connected together to form a path along which gases flow. In some embodiments, the pressure within the source flow path 104 decreases as the distance from the gas source 102 increases. For example, in such embodiments the pressure of gas within the source flow path 104 decreases from a relatively high pressure within the gas source 102 to a relatively low pressure within the plasma chamber 110.

A capacitive discharge element 106 is located along the source flow path 104 at a first position that is upstream of the plasma chamber 110. The capacitive discharge element 106 is configured use capacitive coupling to generate charged ignition ions 108 with the source flow path 104, which are provided downstream to the plasma chamber 110. In some embodiments, the capacitive discharge element 106 comprises a pair of electrodes located on opposite sides of the source flow path 104. During operation, a neutral gas is provided from the gas source 102 to a position within the source flow path 104 that is between the pair of electrodes. A capacitive discharge between the pair of electrodes ionizes neutral gas particles within the source flow path 104 to generate the ignition ions 108.

An inductively coupled plasma ignition element 112 is in communication with the plasma chamber 110. The inductively coupled plasma ignition element 112 is configured to generate (i.e., to ignite and sustain) an inductively coupled plasma having a high plasma density within the plasma chamber 110 based upon the ignition ions 108 generated by the capacitive discharge element 106. By generating the high density inductively coupled plasma based upon the ignition ions 108, the inductively coupled plasma ignition element 112 is able to easily ignite a plasma having a high plasma density, even at low pressures. In some embodiments, the inductively coupled plasma ignition element 112 may comprise an RF antenna located outside of the plasma chamber 110.

FIG. 2 is a block diagram illustrating some additional embodiments of a disclosed plasma RF ion source 200.

The plasma RF ion source 200 comprises a gas source 102 connected to a plasma chamber 110 by a source flow path comprising one or more gas feed tubes 202. The one or more gas feed tubes 202 are configured to supply a neutral gas from the gas source 102 to the plasma chamber 110. In some embodiments, the one or more gas feed tubes 202 comprise tube structures having an inlet at a first end connected to the gas source 102 and an outlet at a second, opposite end.

The plasma RF ion source 200 further comprises one or more orifices 204 coupled between the outlet at the second end of a gas feed tube 202 and the plasma chamber 110. The one or more orifices 204 provide for a drop in pressure between the gas feed tubes 202 and the plasma chamber 110. For example, in some embodiments, the orifice 204 is chosen so that the conductance of gas from the gas feed tubes 202 to the plasma chamber 110 is sufficiently low to allow for the pressure within the gas feed tubes 202 to be substantially higher than the pressure within the plasma chamber 110.

During operation, the source flow path spans a wide range of pressures. In some embodiments, the gas feed tubes 202 are held at a first pressure region 206 having a first pressure within a first pressure range. The first pressure region 206 remains substantially constant over the length of the gas feed tubes 202, due to the relatively high conductance in the gas feed tubes 202. The relatively high pressure of the first pressure region 206 allows for the capacitive discharge element 106 is to easily ionize neutral gas particles within the gas feed tubes 202 to generate charged ignition ions 108. In some embodiments, the first pressure region 202 may comprise a pressure that ranges from about 1 Torr to about 10⁻³ Torr, for example.

The one or more orifices 204 provide for a transition region 208 between the first pressure region 206 and a second pressure region 208, during which the pressure along the source flow path undergoes a steep drop. The second pressure region 210 has a second pressure within a second pressure range that is lower than the first pressure range. In some embodiments, the second pressure region 210 may comprise a pressure that ranges from about 10⁻² Torr to about 10⁻⁵ Torr, for example.

While the inductively coupled plasma ignition element 112 may typically have a difficult time igniting a plasma within the low pressure of the third pressure region 210, the ignition ions 108 generated within the gas feed tube 202 can be used as a base to enable enhanced excitation of gas particles by the inductively coupled plasma ignition element 112. The excited gas particles collide with neutral dopant gas particles within the plasma chamber 110 to generate a high density inductively coupled plasma.

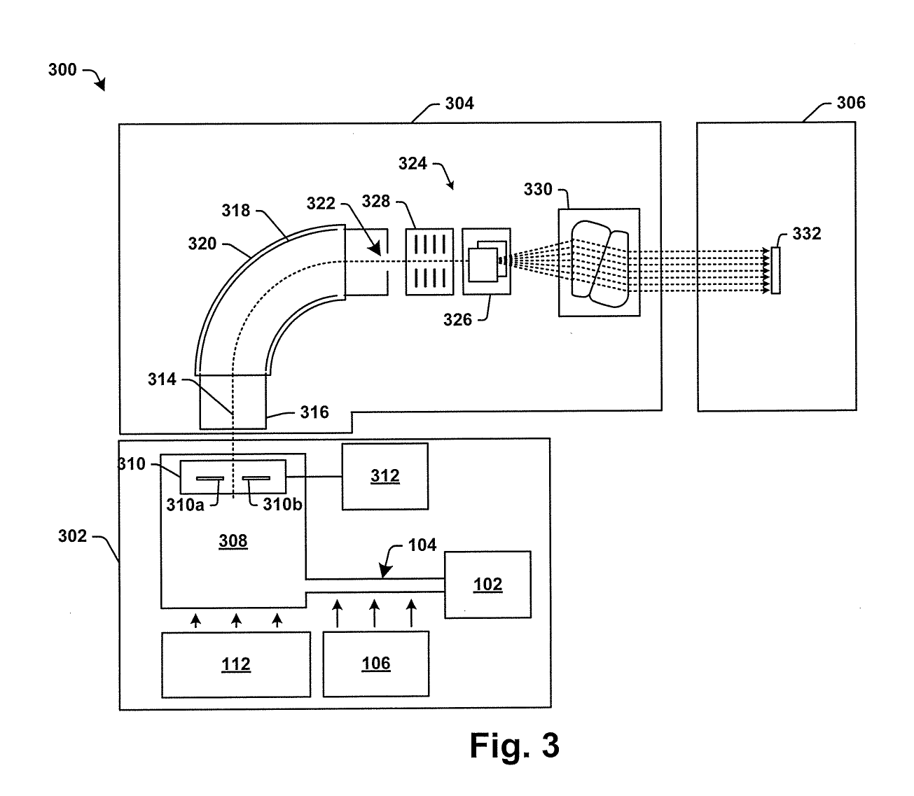

FIG. 3 illustrates an exemplary ion implantation system 300 comprising an inductively coupled plasma ion source that utilizes an inline capacitive ignition. The ion implantation system 300 is presented for illustrative purposes and it is appreciated that aspects of the invention are not limited to the described ion implantation system and that other suitable ion implantation systems can also be employed.

The ion implantation system 300 has a terminal 302, a beamline assembly 304, and an end station 306. The terminal 302 comprises an ion source having a capacitive ignition element 106 and an inductively coupled ignition element 112 as described above.

The ion source generates an inductively coupled plasma having a high plasma density within a plasma chamber 308 held at a low pressure (e.g., 10⁻⁵ Torr). Ions from the plasma are extracted and formed into an ion beam 314, which is directed along a beamline 316 in the beamline assembly 304 to the end station 306. In some embodiments, the ions are controllably extracted through an aperture or slit in the plasma chamber via an ion extraction assembly 310. The extraction assembly 310 comprises a plurality of extraction and/or suppression electrodes 312a, 312b. In some embodiments, the extraction assembly 310 may comprise a separation extraction power supply 312 that provides a bias voltage to the extraction and/or suppression electrodes 310a, 310b.

The beamline assembly 304 has a beamguide 318. In some embodiments, the beamline assembly 304 may further comprise a mass analyzer 320. As the ion beam 314 enters the mass analyzer 320, implantation ions within the ion beam 314 are bent by a magnetic field to have a radius of curvature inversely proportional to their mass. Ions having too great or too small a charge-to-mass ratio are deflected into side walls 118 of the beamguide 316. In this manner, the mass analyzer 116 allows those ions in the ion beam 316 which have the desired charge-to-mass ratio to pass there-through and exit through a resolving aperture 322 comprising an opening located at the end of the mass analyzer 320. In other embodiments, the source material may be sufficiently pure to allow implantation, without mass analysis (i.e., so that the beamline assembly 304 does not comprise a mass analyzer 320).

In various embodiments, the ion implantation system 300 may comprise additional components. For example, as shown in FIG. 3, a magnetic scanning system 324, located downstream of the mass analyzer 320 includes a magnetic scanning element 326 and a magnetic or electrostatic focusing element 328. A scanned beam is passed through a parallelizer 330, which comprises two dipole magnets that cause the scanned beam to alter its path such that the scanned beam travels parallel to a beam axis regardless of the scan angle. The end station 306 then receives the scanned beam which is directed toward a workpiece 332.

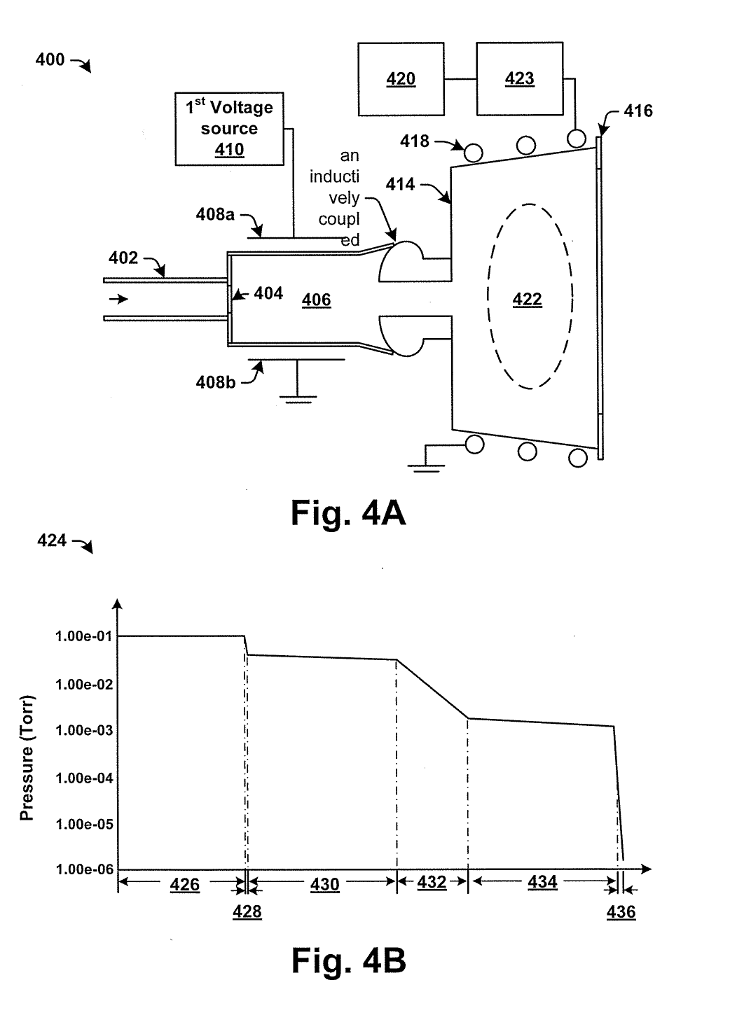

FIG. 4A illustrates some more particular embodiments of a disclosed ion source 400.

The disclosed ion source 400 comprises a gas feed line 402 comprising a conduit that transports a gas from a gas source. An outlet of the gas feed line 402 is connected to an inlet of a gas feed tube 406 by way of a first gas flow restriction 404 disposed between the gas source line 402 and the gas feed tube 406. The first gas flow restriction 404 is configured to generate a pressure drop between the gas feed line 402 and the gas feed tube 406, such that that pressure within the gas feed line 402 is higher than within the gas feed tube 406. In some embodiments, the first gas flow restriction 404 may comprise a passive gas flow restriction component such as a tube shaped element having one or more holes positioned within the flow path of the gas feed line/tube.

A first capacitive plate 408a and second capacitive plate 408b are located on two or more sides of the gas feed tube 406. One of the first or second capacitive plates 408a, 408b is connected to a first power supply 410, while the other capacitive plate is connected to a return terminal or a ground terminal. In some embodiments, the first power supply 410 may comprise a radio-frequency (RF) power supply, operating at a set RF frequency (e.g., 13.56 MHz).

During operation, the first power supply 410 is configured to generate a voltage differential between the first and second capacitive plates 408a and 408b. The voltage differential generates an electric field that passes through the gas feed tube 406. Electrons within a gas in the gas feed tube 406 are accelerated by the electric field and can ionize the gas directly or indirectly (e.g., by collisions). The ionized gas atoms within the gas feed tube 406 form a capacitive discharge comprising ignition ions having a first plasma density, that are within the gas flowing through the gas feed tube 406.

An outlet of the gas feed tube 406 is connected to an inlet of a plasma chamber 414 by way of a second gas flow restriction 412. The ignition ions (e.g., electrons and ions) from the capacitive discharge are provided to the plasma chamber 414 by way of the second gas flow restriction 412. The second gas flow restriction 412 is further configured to generate a pressure drop between the gas feed tube 406 and the plasma chamber 414, such that that pressure within the gas feed tube 406 is higher than within the plasma chamber 414. In some embodiments, the second gas flow restriction 412 may comprise an orifice comprising a plate having one or more holes. As with the first gas flow restriction 404, the dimensions of the orifice can be chosen in conjunction with the dimensions gas feed tube 406 to produce the desired pressure in the plasma chamber 414.

The plasma chamber 414 is wrapped in an inductive coil 418 comprising an RF antenna. The inductive coil 418 is configured to generate an electromagnetic field that transfers energy from a second power supply 420 to gas particles within the plasma chamber 414 to form an inductively coupled plasma 422 having a second plasma density greater than the first plasma density. For example, the time-dependent current produces a time varying magnetic field within the plasma chamber 414, which induces a time-varying electric field that accelerates charged particles such as electrons to an energy that is sufficient to ionize the source gas atoms within the plasma chamber 414 by way of ionizing collisions. The ignition ions from the capacitive discharge provide free charges that help to ignite the inductively coupled plasma 422 within the plasma chamber 414. The plasma chamber 414 comprises an arc slit 416 at one end through which the inductively coupled plasma 422 is output to an ion beam line.

In some embodiments, the first power supply 410 operating the capacitive plates 408a, 408b is independent of the second power supply 420 driving the inductive coil 418. In other embodiments, the first power supply 410 is the same as the second power supply 420 driving the inductive coil 418. For example, in some embodiments, the first and second capacitive plates, 408a and 408b, may be extensions of leads used to drive the inductive coil 418.

In some embodiments, the inductive coil 418 comprises a conductive wire or tube wrapped around an outside surface of the plasma chamber. The inductive coil 418 may be water cooled in some embodiments, while in other embodiments, the inductive coil 418 is not water cooled. The inductive coil 418 comprises a first coil end and a second coil end. The first coil end is electrically connected to a first output terminal of a second power supply 420 and the second coil is connected to a ground terminal. In some embodiments, the second power supply 420 comprises an RF power generator that operates at a set RF frequency (e.g., 13.56 MHz) to generate a time dependent current that is provided to the inductive coil 418. In other embodiments, the second power supply 420 comprises a DC power generator. In some embodiments, second power supply 420 may be connected to the antenna by way of a matching network 423. The matching network 423 is configured to match the output impedance of the second power supply 420 to a complex impedance established by the inductive coil 418 and the impedance of the plasma 422, thereby efficiently coupling power from the second power supply 420 to the plasma 422. In some embodiments, the first power supply 410 and the second power supply 420 are the same power supply, such that both the inductive coil and the capacitive plates can be driven by the same power supply.

In various embodiments, the first gas flow restriction 404 may comprise a metal (e.g., stainless steel), metal alloy, glass, ceramic or thermoplastics and have dimensions chosen in conjunction with the dimensions gas feed line 402 to produce the desired pressure in gas feed tube 406. The gas feed tube 406 comprises an electrically non-conductive tube, which allows the electric field from the capacitive plates 408a, 408b to penetrate through walls of the gas feed tube 406. In some embodiments, the gas feed tube 406 may comprise quartz, for example. In some embodiments, the plasma chamber 414 may comprise outside surfaces that are made from an electrically non-conductive material to allow the electromagnetic field from the inductive coil 418 to penetrate through outside surfaces of the plasma chamber 414. In other embodiments, the outside surface of the plasma chamber 414 may take the form of a Faraday Cage, comprising metal or another conductive material, while still allowing the electromagnetic field from the inductive coil 418 to penetrate. In some embodiments, the outside surface of the plasma chamber 414 may comprise quartz, for example.

In some embodiments, one or more additional coils are positioned around the perimeter of the plasma chamber 414 (e.g., wrapped around the plasma chamber 414). In some embodiments, the one or more additional coils comprise a Helmholtz pair, for example. The one or more additional coils are connected to an additional power supply configured to generate an AC or DC signal. During operation the additional coils are operated to generate an additional AC or DC magnetic field that extends into the plasma chamber 414 to an additional DC or AC magnetic field. The additional AC of DC magnetic fields enhance operation of the plasma system by providing for higher density of operation and/or other plasma modes (e.g. helicon operation).

FIG. 4B illustrates a graph 424 showing an exemplary pressure profile along the source flow path of ion source 400. Graph 424 illustrate that pressure changes along the source flow path of a disclosed ion source are determined by a base pressure in a gas source region and the various conductance from the gas feed line through different components of the ion source.

It will be appreciated that the pressure values shown in graph 424 are only exemplary pressure values to aid the reader in understanding and are not intended to limit the scope of the disclosed ion source, in any way. For example, although the capacitive discharge element is shown as operating upon a gas feed tube held at a pressure between 10⁻¹ Torr and 10⁻² Torr, the capacitive discharge element is not limited to operate at such pressures.

A first region 426 of graph 424 corresponds to a pressure within the gas feed line 402. The pressure within the first region 426 is substantially constant over the length of the gas feed line 402, due to relatively good conductance.

A second region 428 of graph 424 corresponds to a pressure within the first gas flow restriction 404 connecting the gas feed line 402 to a gas feed tube 406. The pressure within the second region 428 undergoes a sharp drop due to the first gas flow restriction 404, resulting in a pressure that is by approximately a half order of magnitude lower in the gas feed tube 406 than in the gas feed line 402.

A third region 430 of graph 424 corresponds to a pressure within the gas feed tube 406. The pressure within the third region 430 is substantially constant over the length of the gas feed tube 406, due to the relatively high conductance in the gas feed tube 406, and is sufficiently high to enable the capacitive discharge element to form ignition ions by way of capacitive coupling.

A fourth region 432 of graph 424 corresponds to a pressure within the second gas flow restriction 412 connecting the gas feed tube 406 to the plasma chamber. The pressure within the fourth region 432 undergoes a sharp drop due to the second gas flow restriction 412, resulting in a pressure that is by approximately an order of magnitude lower in the plasma chamber 414 than in the gas feed tube 406.

A fifth region 434 of graph 424 corresponds to a pressure within the plasma chamber 414. Within the plasma chamber the pressure is relatively constant and is lower than in the gas feed tube 416.

A sixth region 436 of graph 424 corresponds to a pressure within the arc slit 416. The pressure within the sixth region 436 undergoes a sharp drop due to the arc slit 416, resulting in a pressure that is by approximately three orders of magnitude lower in the beam line than in the plasma chamber 414.

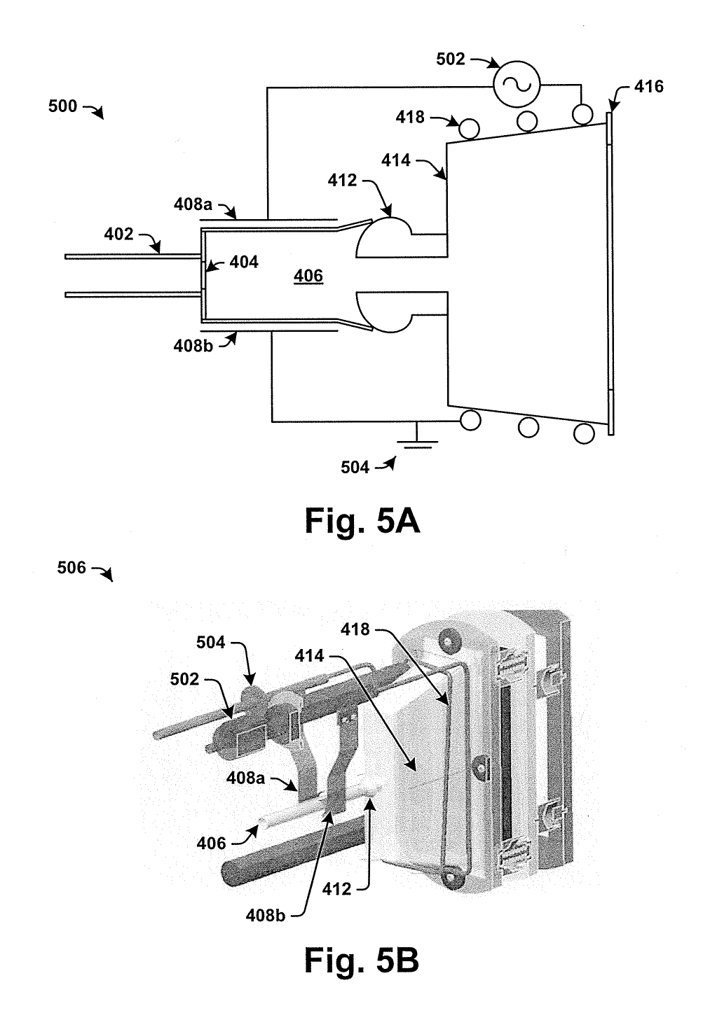

FIG. 5A illustrates some alternative embodiments of a disclosed ion source 500. The disclosed ion source 500 comprises a power supply 502 is configured to generate a high voltage. The power supply 502 comprises an output node that is connected to a first capacitive plate 408a of a capacitive discharge element and to a first end of an inductive coil 418 of an inductively coupled plasma generation element. A ground terminal 504 is connected to a second capacitive plate 408b of the capacitive discharge element and to a second end of the inductive coil 418.

FIG. 5B illustrates a three dimensional illustration of ion source 506. The reference numerals of FIG. 5B denote the same elements as the reference numerals shown in FIGS. 4A and 5A.

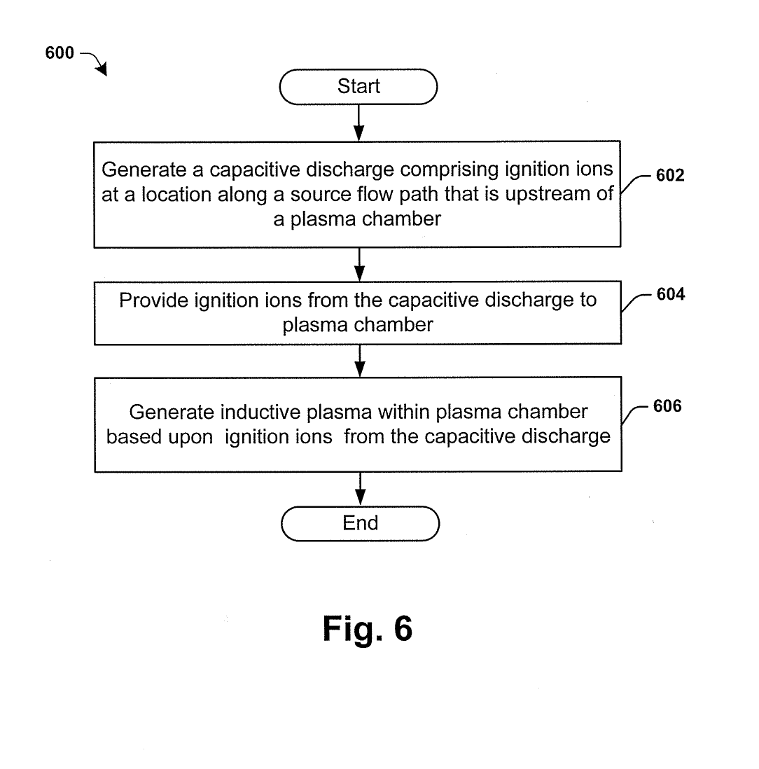

FIG. 6 illustrates some embodiments of an exemplary method 600 for igniting an inductively coupled plasma. The method uses an inline capacitive discharge to produce ignition electros for a main inductively coupled plasma ion source.

While method 600 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the disclosure herein. Also, one or more of the acts depicted herein may be carried out in one or more separate acts and/or phases.

At 602 a capacitive discharge comprising ignition ions is generated along a source flow path at a position that is upstream of a plasma chamber. The capacitive discharge is generated using a capacitive coupling. In some embodiments, the capacitive discharge is generated by forming an electric field within a gas feed tube located at a position upstream of the plasma chamber. The electric field generates ignition ions comprising ions and/or electrons within the gas feed tube as described above.

At 604 ignition ions from the capacitive discharge are provided to the plasma chamber. In some embodiments, the ignition ions may be provided from a gas feed tube having a first pressure to a plasma chamber having a second pressure lower than the first pressure.

At 606 an inductively coupled plasma is generated within the plasma chamber based upon the ignition ions from the capacitive discharge. The inductively coupled plasma has a higher plasma density than the capacitive discharge. In some embodiments, the inductively coupled plasma is generated by operating upon the ignition ions using a time varying magnetic field to ignite a plasma within the plasma chamber.

Although the invention has been shown and described with respect to a certain aspects and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the invention. In this regard, it will also be recognized that the invention includes a computer-readable medium having computer-executable instructions for performing the steps of the various methods of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “including”, “has”, “having”, and variants thereof are used in either the detailed description or the claims, these terms are intended to be inclusive in a manner similar to the term “comprising”.

What is claimed is:

1. An ion implantation system, comprising:
a source flow path along which dopant gas particles are conveyed from a gas source to a plasma chamber;
a capacitive discharge element located at a first position along the source flow path and configured to use capacitive coupling upon the gas to form a capacitive discharge comprising ignition ions, which are provided downstream to the plasma chamber; and
an inductively coupled plasma ignition element in communication with the plasma chamber and configured to induce and sustain a high density plasma within the plasma chamber facilitated by the ignition ions formed by the capacitive discharge element.

2. The ion implantation system of claim 1,
wherein the source flow path comprises one or more gas feed tubes comprising a tube structure having an inlet at a first end connected to the gas source and an outlet at a second end connected to the plasma chamber; and
wherein the capacitive discharge element comprises a first electrode and a second electrode, which are positioned along opposite sides of the one or more gas feed tubes.

3. The ion implantation system of claim 2, wherein the first electrode of the capacitive discharge element is electrically connected to a return terminal or a ground terminal and the second electrode of the capacitive discharge element is electrically connected to an output node of a first power supply that is configured to provide a high voltage differential between the first and second electrodes.

4. The ion implantation system of claim 3, wherein the inductively coupled plasma ignition element comprises an inductive coil wrapped around an outside surface of the plasma chamber, the inductive coil comprising a first end electrically connected to an output node of a second power supply and a second end electrically connected to a ground terminal.

5. The ion implantation system of claim 4, wherein the outside surface of the plasma chamber comprises a non-conductive material.

6. The ion implantation system of claim 5, wherein the outside surface of the plasma chamber comprises a Faraday cage including a conductive material.

7. The ion implantation system of claim 4, further comprising one or more additional coils positioned around the perimeter of the plasma chamber and configured to generate an AC or DC magnetic field that extend into the plasma chamber.

8. The ion implantation of claim 4, wherein the output node of the first power supply is the same as the output node of the second power supply, such that the first electrode of the capacitive discharge element is electrically connected to the first end of the inductive coil.

9. The ion implantation system of claim 2, wherein the source flow path further comprises:
a first gas flow restriction located between an outlet of one of the gas feed tubes and an inlet of the plasma chamber, wherein the first gas flow restriction is configured to provide for a first pressure range within the gas feed tube that is higher than a second pressure range within the plasma chamber.

10. The ion implantation system of claim 9, wherein the source flow path further comprises:
a second gas flow restriction located between the gas source and an inlet of one of the gas feed tubes, wherein the second gas flow restriction is configured to provide for a third pressure range within the gas source that is higher than the first pressure range within the gas feed tube.

11. The ion implantation system of claim 2, wherein the one or more gas feed tubes comprise a non-conductive material.

12. An ion implantation system, comprising:
a gas feed tube configured to provide a neutral gas from a gas source to a plasma chamber in communication with an ion beam line;
a capacitive discharge element comprising a first electrode and a second electrode, which are positioned along opposite sides of the one or more gas feed tubes and that are configured to generate an electric field within the gas feed tube that operates to induce a capacitive discharge comprising a plurality of ignition ions within the gas feed tube, wherein the capacitive discharge has a first plasma density; and
an inductively coupled plasma ignition element in communication with the plasma chamber and configured to generate a time varying magnetic field within the plasma chamber that induces an inductively coupled plasma having a second density greater than the first density based upon the ignition ions from the gas feed tube.

13. The ion implantation system of claim 12, further comprising a first gas flow restriction located between an outlet of the gas feed tube and an inlet of the plasma chamber, wherein the first gas flow restriction is configured to provide for a first pressure range within the gas feed tube that is higher than a second pressure range within the plasma chamber.

14. The ion implantation system of claim 12, further comprising
a second gas flow restriction located between the gas source and an inlet of the gas feed tubes, wherein the second gas flow restriction is configured to provide for a third pressure range within the gas source that is higher than the first pressure range within the gas feed tube.

15. The ion implantation system of claim 12, wherein the first electrode of the capacitive discharge element is electrically connected to a ground terminal and the second electrode of the capacitive discharge element is electrically connected to an output node of a first power supply that is configured to provide a high voltage differential between the first and second electrodes.

16. The ion implantation system of claim 12, wherein the inductively coupled plasma ignition element comprises an inductive coil wrapped around an outside surface of the plasma chamber, the inductive coil comprising a first end electrically connected to an output node of a second power supply and a second end electrically connected to a ground terminal.

17. The ion implantation of claim 16, wherein the first electrode of the capacitive discharge element is electrically connected to the ground terminal and the second electrode of the capacitive discharge element is electrically connected to the output node of the second power supply.

18. The ion implantation system of claim 12, wherein the one or more gas feed tubes comprise a non-conductive material.

19. A method for igniting an inductively coupled plasma, comprising:
generating a capacitive discharge comprising ignition ions at a first location along a source flow path that is upstream of a plasma chamber;
providing the ignition ions to the plasma chamber located downstream of the first location; and
generating an inductively coupled plasma within the plasma chamber based upon the ignition ions generated by the capacitive discharge.

20. The method of claim 19, wherein the capacitive discharge is generated in a gas feed tube configured to provide a dopant gas from a gas source to the plasma chamber.
